(19) United States
(12) Patent Application Publication
(10) Pub. No.: US 2014/0184313 A1
(43) Pub. Date: Jul. 3, 2014

(54) TOUCH SENSING DEVICE AND A PROGRAMMABLE CONTROLLER THEREOF

(71) Applicants: Kai-Chu Chuang, Zhushan (TW); Ta-Kang Chou, Yongkang (TW)

(72) Inventors: Kai-Chu Chuang, Zhushan (TW); Ta-Kang Chou, Yongkang (TW)

(21) Appl. No.: 13/728,988

(22) Filed: Dec. 27, 2012

(51) Int. Cl. H03K 17/96

(52) U.S. Cl. CPC H03K 17/96
USPC 327/517

(57) ABSTRACT

A programmable controller used in a touch sensing device comprises a plurality of general pins, a control circuit, and a plurality of switching units. The control circuit records corresponding relationship between a plurality of general pins and a plurality of sensing lines and driving lines of the touch panel. The switching units are correspondingly connected with the general pins, and separately receive a switching signal produced by the control circuit, wherein the control circuit produces the switching signal based on the corresponding relationship, and wherein each of the switching units selectively connects the correspondingly connected general pin to a sensing circuit or a driving circuit based on the received switching signal. The programmable controller can be for designers to set the corresponding relationship between the general pins and the driving lines and the sensing lines, such that the programmable controller is applicable to different standards of the touch panel.

### BACKGROUND OF THE INVENTION

This Application claims the benefit of the People's Republic of China Application No. 201110461261.X, filed on Dec. 30, 2011.

1. Field of the Invention

The present disclosure relates to a touch sensing device. More particularly, the present disclosure relates to a programmable controller and a touch sensing device employing the same.

2. Description of the Related Art

With improvement of design technologies relating to semiconductor and electric circuits, touch sensing devices are gradually being applied in handheld devices and other electronic devices as human interfaces for receiving touch input signals produced by the touch sensing devices.

With reference to FIG. 1A, FIG. 1A is a functional block diagram of a traditional touch sensing device. The touch sensing device 10 comprises a touch panel 101 and a controller 102, wherein the touch panel 101 is, for example, a projected capacitive touch panel, and comprises a plurality of driving lines D0˜D27 and a plurality of sensing lines S0˜S14. The driving lines D0˜D27 and the sensing lines S0˜S14 crosswise form a sensing electrode array, and junction of each of the driving lines D0˜D27 and each of the sensing lines S0˜S14 coupling-forms a capacitance (not shown). Moreover, the driving lines D0˜D27 and the sensing lines S0˜S14 are further respectively connected with driving pins D0′˜D27′ and sensing pins S0′˜S14′ of the controller 102 through wires. Accordingly, the controller 102 produces driving signals to the driving lines D0˜D27 in sequence, and receives sensing signals of the sensing lines S0˜S14 in sequence, so as to calculate capacitance change of each capacitance on the sensing electrode array based on the received sensing signals, thereby determining touch areas on the touch panel 101 by users.

A design of the traditional touch sensing device 10 normally chooses an applicable controller 102 for collocation after obtaining required standards of the touch panel 101 such as size of panel, sensing resolution and the like. However, the controller 102 has a specific standard in design, namely, location and number of the driving pins D0′˜D27′ and sensing pins S0′˜S14′ of the controller 102 are fixed after design is accomplished, so that each kind of controllers is not easily applied in different standards of touch panel, and has more application restrictions. Accordingly, controller manufacturers normally reserve the sensing pins and/or the driving pins as much as possible in the design so as to be able to support different standards of touch panel. For example, the controller 102 designed as FIG. 1A can support a touch panel with maximum 16 sensing lines and 32 driving lines.

The foregoing design of reserving more sensing pins and/or driving pins has a better applicability. However, as the location and number of sensing pins and driving pins of a controller are still fixed, the desired flexibility is reduced. With reference to FIG. 1B, FIG. 1B is a functional block diagram of another traditional touch sensing device that illustrates a practical situation that the controller cannot support a touch panel. A controller 112 of FIG. 1B has 16 sensing pins S0′˜S15′ and 32 driving pins D0′˜D31′, and a touch panel 111, on the other hand, has 18 sensing lines S0˜S17 and 27 driving lines D0˜D26. Accordingly, the controller 112 would face an inapplicable situation, wherein the sensing pins S0′˜S15′ cannot handle all of the sensing lines S0˜S17 of the touch panel 111, and the driving pins D0′˜D31′ are more than all of the driving lines D0˜D26 of the touch panel 111.

Moreover, since location of the sensing pins and the driving pins of the traditional controller is fixed, circuit layout between the controller and the driving lines and sensing lines of the touch panel has a certain difficulty. With reference to FIG. 1C, FIG. 1C is a functional block diagram of another traditional touch sensing device. As shown in FIG. 1C, sensing lines S0˜S7 and S8˜S14 of a touch panel 121 are respectively located at upper right side and lower left side of the touch panel 121. In order to correspondingly connect to the sensing pins S0′˜S7′ and the sensing pins S8′˜S14′ of the controller 122 respectively, the wires which are used for connecting the sensing pins S0′˜S14′ and the sensing lines S0˜S14 on the circuit board or flexible board form a cross-alignment layout. Therefore, the situation of cross-alignment can only be solved by increasing the layer number of circuit boards or flexible boards in design. However, the signals transmitted in the wires are analog signals with small amount of signals, so that those intercrossed wires are easily interfered with each other, and electrical performance of the whole touch sensing device is declined, more seriously, the case of error would occur.

### SUMMARY OF THE INVENTION

The present disclosure provides a touch sensing device and a programmable controller thereof, wherein the programmable controller is used for designing the touch sensing device and for setting corresponding relationship between a plurality of general pins of the programmable controller and a plurality of driving lines and a plurality of sensing lines of a touch panel. So that the programmable controller can flexibly set each general pin as driving pin or sensing pin to correspond to different standards of touch panel, and to effectively optimizing circuit layout between the touch panel and the programmable controller.

The present disclosure provides a programmable controller, wherein the programmable controller comprises a plurality of general pins, a control circuit, and a plurality of switching units. The control circuit is used for recording corresponding relationship between the general pins and a plurality of sensing lines and a plurality of driving lines of a touch panel. The switching units are correspondingly connected with the general pins, and separately receive a switching signal produced by the control circuit, wherein the control circuit produces the switching signal based on the corresponding relationship. Each of the switching units selectively connects the correspondingly connected general pin to a sensing circuit or driving circuit based on the received switching signal.

The present disclosure also provides a touch sensing device, wherein the touch sensing device comprises a touch panel and the foregoing programmable controller. The touch panel has a plurality of sensing lines and a plurality of driving lines.

In an embodiment of the present disclosure, the control circuit further controls switching operation of the switching units through controlling producing sequence of the switching signal.

In another embodiment of the present disclosure, when the control circuit controls each of the general pins, which is correspondingly connected with the driving lines, to selectively connect to the driving circuit for transmitting a driving signal produced by the driving circuit to the correspondingly connected driving lines, the control circuit also controls all of the general pins, which are correspondingly connected with the sensing lines, to selectively connect to the sensing circuit in sequence for transmitting a sensing signal coupling-produced by the correspondingly connected sensing line to the sensing circuit.

In another embodiment of the present disclosure, the control circuit further simultaneously controls two switching units, which are correspondingly connected to the sensing lines, to selectively connect to two input terminals of the sensing circuit.

In another embodiment of the present disclosure, each of the switching units further selectively connects the correspondingly connected general pin to a reference voltage terminal or a high impedance terminal based on the received switching signal.

In another embodiment of the present disclosure, each of the switching units is designed with a combination of switches, a selector, or a multiplexer.

In another embodiment of the present disclosure, the programmable controller is a single-chip system for integrating the control circuit, the switching units, the driving circuit, and the sensing circuit.

In another embodiment of the present disclosure, the control circuit comprises a memory unit, an accessing control unit, and a signal producing unit. The accessing control unit connects to the memory unit for receiving the corresponding relationship, and then records the corresponding relationship into the memory unit. The signal producing unit is connected to the accessing control unit to obtain the corresponding relationship from the memory unit through the accessing control unit, and produces the switching signals based on the corresponding relationship.

In conclusion, the programmable controller of the touch sensing device provided by the present disclosure can correspond to different standards of touch panel so as to increase application flexibility of the programmable controller, and can improve utilization of all of the general pins of the programmable controller. In addition, function of each general pin of the programmable controller such as driving or sensing, which can he set based on practical outlet location of the sensing lines and the driving lines of the touch panel and location of the general pins of the programmable controller, so as to eliminate obsession of circuit layout on the circuit board or flexible board and avoid the wires, which are used for connecting the touch panel and the programmable controller on the circuit board or the flexible board, forming cross-alignment.

In order to further understand characteristics and technical aspects of the present disclosure, several descriptions accompanied with drawings are described in detail below. However, descriptions and accompanying drawings are for purposes of reference and specification only and not for limiting scope of the present disclosure.

### BRIEF DESCRIPTION OF THE DRAWINGS

FIG. 1A is a functional block diagram of a traditional touch sensing device;

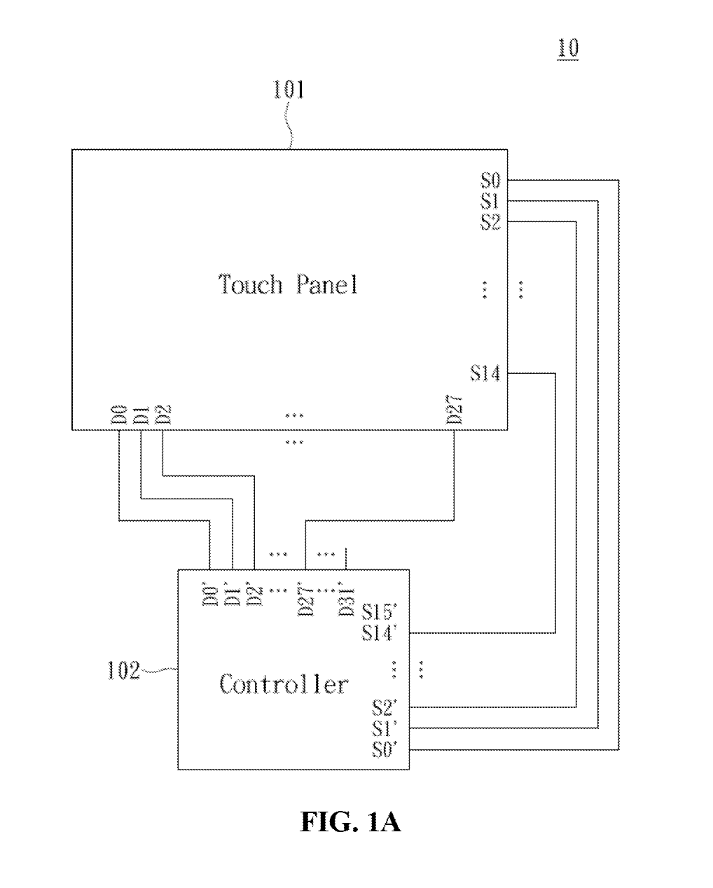

FIG. 1B is a functional block diagram of another traditional touch sensing device;

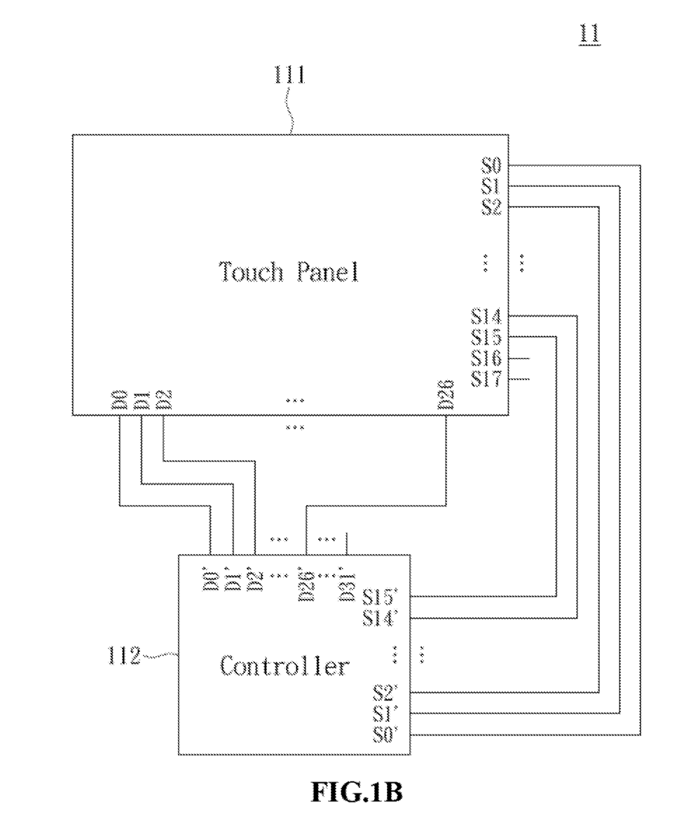

FIG. 1C is a functional block diagram of another traditional touch sensing device;

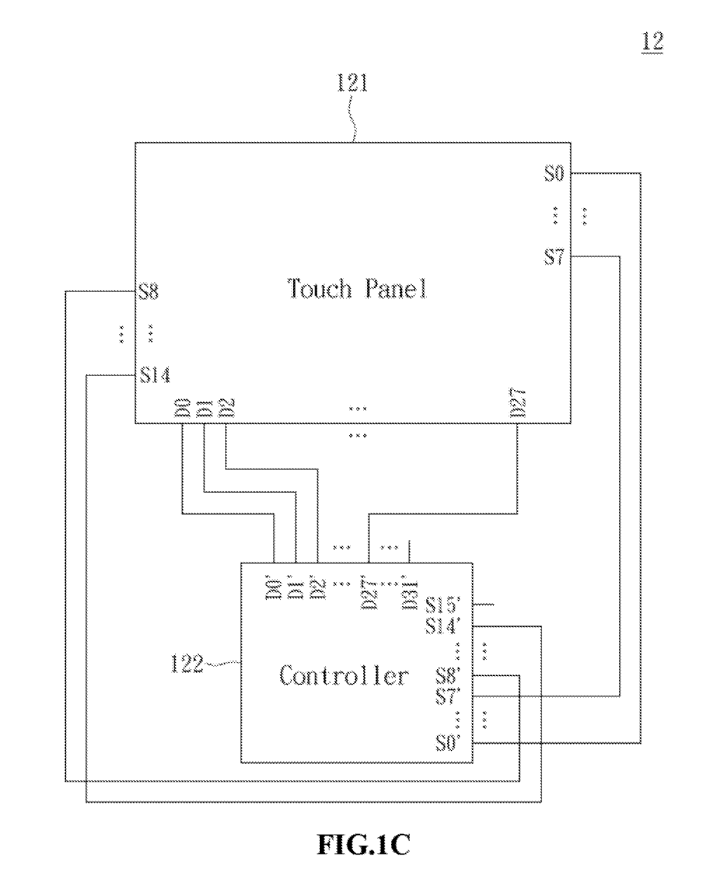

FIG. 2 is a functional block diagram of a touch sensing device in accordance with an embodiment of the present disclosure;

FIG. 3A is a detailed circuit diagram of a touch sensing device in accordance with an embodiment of the present disclosure;

FIG. 3B is a detailed circuit diagram of a touch sensing device in accordance with another embodiment of the present disclosure;

FIG. 4 is a functional block diagram of a control circuit in accordance with an embodiment of the present disclosure;

FIG. 5A is a diagram of corresponding relationship recorded by a memory unit in accordance with an embodiment of the present disclosure; and

FIG. 5B is a diagram of corresponding relationship recorded by the memory unit in accordance with another embodiment of the present disclosure.

### DETAILED DESCRIPTION OF THE EMBODIMENTS

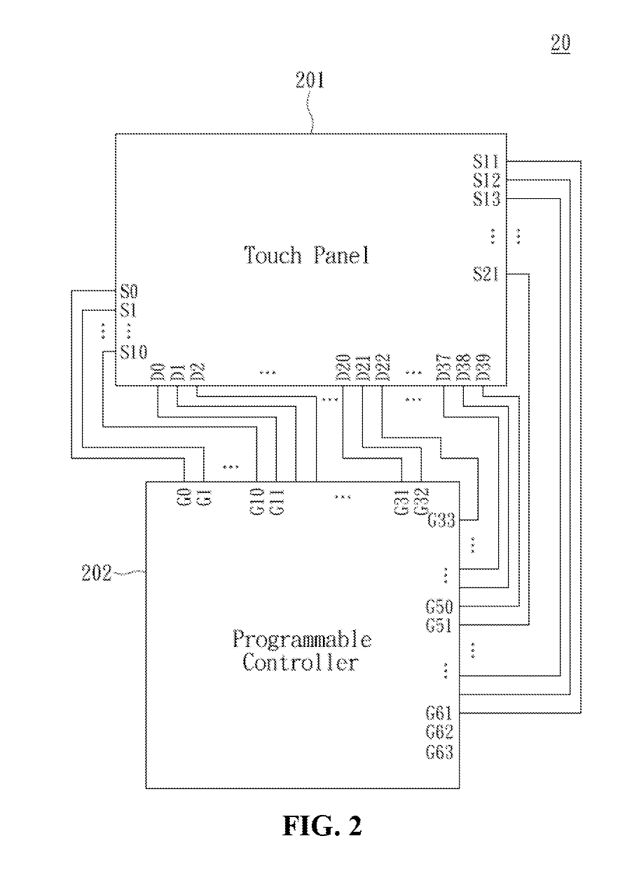

With reference to FIG. 2, FIG. 2 is a functional block diagram of a touch sensing device in accordance with an embodiment of the present disclosure. A touch sensing device 20 comprises a touch panel 201 and a programmable controller 202. The touch panel 201 comprises a plurality of sensing lines S0˜S21 and a plurality of driving lines D0˜D39, wherein the sensing lines S0˜S21 and the driving lines D0˜D39 are electrically insulated from each other and crosswise form a sensing electrode array for providing a touch sensing function. In addition, the programmable controller 202, which is different from a traditional controller, comprises a plurality of general pins G0˜G63. Designers of the touch sensing device 20 can self-define the function of each of the general pins G0˜G63 of the programmable controller 202 based on circuit layout, which is conformed with wiring rules, between the touch panel 201 and the programmable controller 202. Therein, the function of each of the general pins G0˜G63 can be defined as driving or sensing, and the wiring rules can be as avoiding cross-alignment and limiting wiring length of the sensing lines and the driving lines and the like. In other words, any of the general pins G0˜G63 can be a sensing pin or a driving pin as desired by the designer.

In an embodiment, circuit layout of the touch sensing device 20 can be designed based on standards of the touch panel 201. For instance, the circuit layout can be based on one or more of dimension, scale, and sensing resolution of the touch panel 201. The circuit layout can further be designed based on outlet location of the driving lines and the sensing lines so as to avoid the sensing lines S0˜S10 and S11˜S21, which are respectively connected to general pins G0˜G10 and G61˜G51, from getting connected to the driving lines D0˜D39, which are respectively connected to the general pins G11˜G50 under a situation of cross-alignment. Therefore, designers can further define a function for each general pin G0˜G63 of the programmable controller 202 based on the accomplished circuit layout so as to respectively define the general pins G0˜G10 and G61˜G51 as sensing pins which are used for receiving the sensing signals of the sensing lines S0˜S10 and S11˜S21, and so as to respectively define the general pins G11˜G50 as driving pines which are used for transmitting the driving signals to the driving lines D0˜D39.

Moreover, in order to avoid cross-alignment, the general pins G0˜G63 of the programmable controller 202 are not correspondingly connected with the sensing lines S0˜S21 and the driving lines D0˜D39 of the touch panel 201 in numerical order. Therefore, the programmable controller 202 can further manage the operation of all of the general pins G0˜G63 based on corresponding relationship between the general pins G0˜G63 and the sensing lines S0˜S21 and driving lines D0˜D39 to efficiently control functions of the sensing lines S0˜S21 and the driving lines D0˜D39 of the touch panel 201. It is to be noted that, the corresponding relationship can be designed through a comparison table. However, appearance, design, and layout of such a table is not limited the present disclosure.

In practice, the programmable controller 202 can transmit driving signals to the correspondingly connected driving lines D0˜D39 through general pins G11˜G50, which are interchangeably defined as driving pins, in sequence. The programmable controller 202 can additionally receive sensing signals through the general pins G0˜G10 and G61˜G51, which are interchangeably defined as sensing pins, while transmitting the driving signal to the correspondingly connected driving line D0˜D39 through any of the general pins G11˜G50, which are interchangeably defined as driving pin. Accordingly, the programmable controller 202 can respectively aim at each of the driving lines D0˜D39 to receive all of the sensing signals from the sensing lines S0˜S21, and then completes scanning of the whole sensing electrode array and further determines touch area on the touch panel 201 by users based on all of the received sensing signals. Scanning sequence of the sensing electrode array by the programmable controller 202 is not limited by the present disclosure, and the programmable controller 202 can further transmit the driving signals and receive the sensing signals in a sequence defined by the designers.

In addition, in comparison with the fact that the number of driving pins and sensing pins of a traditional controller must be respectively more than the number of driving lines and sensing lines of a touch panel, the programmable controller 202 of the present disclosure has greater flexibility, and can be applied in any touch panel with equal or less number of driving lines and sensing lines when compared with the number of general pins of the programmable controller 202. For example, the programmable controller 202 can be applied to each standard of the touch panel that has 64 or less driving lines and sensing lines in total.

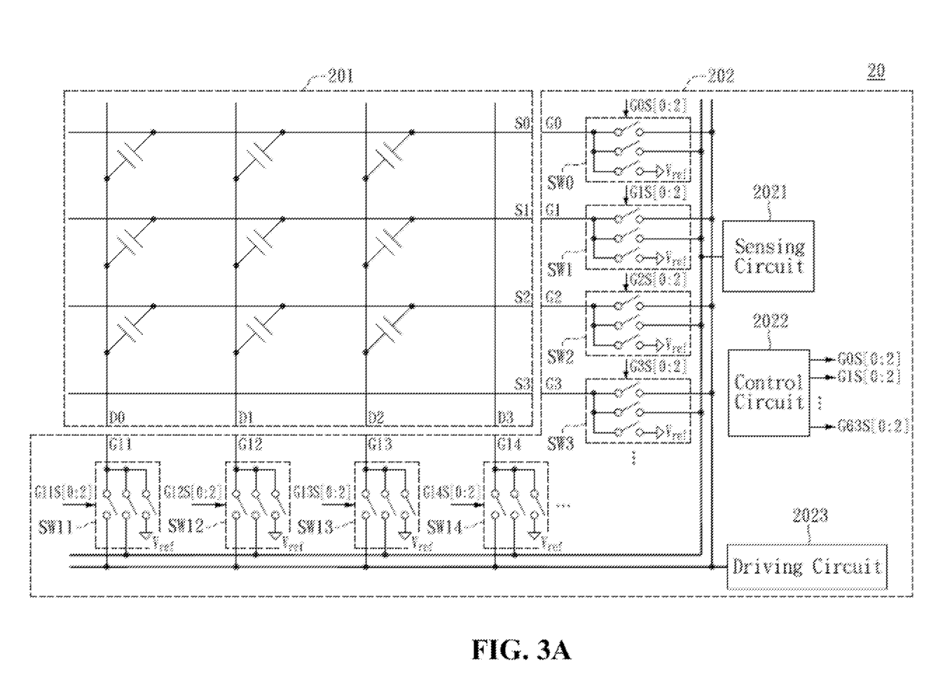

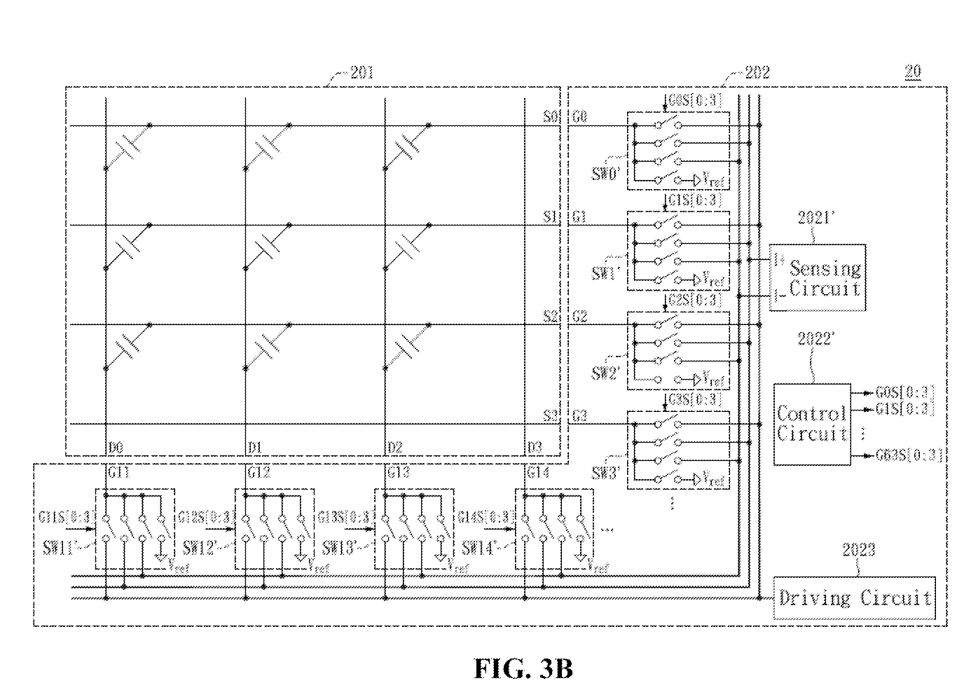

In order to further illustrate circuit structure and operational situation of the touch sensing device 20, referring to FIG. 3A based on FIG. 2, FIG. 3A is a detailed circuit diagram of a touch sensing device in accordance with an embodiment of the present disclosure. FIG. 3A shows a part of the sensing electrode array that is crosswise formed by four driving lines D0˜D3 and four sensing lines S0˜S3, wherein the junction of each of the driving lines D0˜D3 and each of the sensing lines S0˜S3 coupling-forms a capacitance.

The programmable controller 202 comprises a sensing circuit 2021, a control circuit 2022, a driving circuit 2023, and a plurality of switching units SW0˜SW63 correspondingly connected to the general pins G0˜G63, wherein the control circuit 2022 records defined corresponding relationship between the general pins G0˜G63 and the sensing lines S0˜S21 and driving lines D0˜D39. The switching units SW0˜SW63 are connected to the control circuit 202, and separately receive a switching signal G0S[0:2]˜G63S[0:2] produced by the control circuit 202 based on the corresponding relationship, wherein each of the switching units SW0˜SW63 selectively connects the correspondingly connected general pins G0˜G63 to the driving circuit 2023, the sensing circuit 2021 or a reference voltage terminal Vref such as ground or voltage source based on the received switching signals G0S[0:2]˜G63S[0:2]. In addition, the reference voltage terminal Vref of other embodiments can be eliminated or replaced by a high impedance terminal. Furthermore, the driving circuit 2023 produces driving signals such as sinusoidal signals, and the sensing circuit 2021 receives sensing signals and determines touch area on the touch panel 201 based on the sensing signals.

In practical design, except for producing switching signals G0S[0:2]˜G63S[0:2] based on the corresponding relationship, the control circuit 2022 can further control the producing sequence of the switching signals G0S[0:2]˜G63S[0:2] to control the switching operation of the switching units SW0˜SW63. In other words, under a condition of existing the corresponding relationship, the control circuit 2022 can control the sequence of driving signals being transmitted to the general pins G11˜G50, which are defined as driving pins and the sequence of sensing signals being received by the general pins G0˜G10 and G61˜G51, which are defined as sensing pins according to the scanning order that is required by practical design.

For example, the control circuit 2022 controls the switching units SW11˜SW50, which are correspondingly connected with the driving lines D0˜D39 one by one to selectively connect to the driving circuit 2023 for transmitting the driving signals produced by the driving circuit 2023 to the correspondingly connected driving lines D0˜D39 in sequence. When the control circuit 2022 controls any of the switching units SW11˜SW50, which is correspondingly connected with the driving lines D0˜D39 to selectively connect to the driving circuit 2023, the control circuit 2022 additionally controls all of the switching units SW0˜SW1 and S61˜S51, which are correspondingly connected with the sensing lines S0˜S21 to selectively connect to the sensing circuit 2021 in sequence in order for transmitting the sensing signals, which are correspondingly connected with the sensing lines S0˜S21 to the sensing circuit 2021, so that the sensing circuit 2021 can respectively aim at one of the driving lines D0˜D39 to receive all of the sensing signals of the sensing lines S0˜S21.

It is to be noted that, the sensing circuit 2021, in accordance with the embodiment of FIG. 3A, obtains the sensing signals by a single-terminal sensing method. In this embodiment, the switching units SW0˜SW63 are respectively designed with a combination of three switches, and selectively connect the correspondingly connected general pins G0˜G63 to the driving circuit 2023, the sensing circuit 2021 or a reference voltage terminal Vref based on signal value of the switching signals G0S[0:2]˜G63S[0:2]. In such a case, the programmable controller 202 in default value is to control all the switching units SW0˜SW63 to connect to the reference voltage terminal Vref so that the correspondingly connected general pins G0˜G63 can be kept at a voltage value when the switching units SW0˜SW63 have not been controlled to connect to the sensing circuit 2021 or the driving circuit 2022, and the driving lines D0˜D39 and the sensing lines S0˜S21, which are connected with the switching units SW0˜SW63, are avoided being interfered to float.

For corresponding to the embodiment of FIG. 2, in FIG. 3A, the switching units SW0˜SW3, namely the general pins G0˜G3, are respectively connected with the sensing lines S0˜S3, and the switching units SW11˜SW14, namely the general pins G11˜G14, are respectively connected with the driving lines D0˜D3. In addition, each of the switching signals G0S[0:2]˜G63S[0:2] is a 3 bits signal. For instance, when signal value equals to [001], it means selectively connecting to the driving circuit 2023; when signal value equals to [010], it means selectively connecting to the sensing circuit 2021; and when signal value equals to [100], it means selectively connecting to the reference voltage terminal Vref. However, it is to be noted that implementation of the switching units SW0˜SW63 and the type of switching signals G0S[0:2]˜G63S[0:2] are not limited by the present disclosure. In another embodiment, each of the switching units SW0˜SW63 can be designed with a multiplexer or a selector.

With reference to FIG. 3B, FIG. 3B is a detailed circuit diagram of a touch sensing device in accordance with another embodiment of the present disclosure. Structure and operation of the embodiment of FIG. 3B is mostly same as those of the embodiment of FIG. 3A, wherein the difference lies in that the sensing circuit 2021′ of FIG. 3B uses a differential sensing method to obtain sensing signals. In other words, the sensing circuit 2021′ of this embodiment is designed with a dual-channel having two input terminals I+ and I−. Moreover, each of the switching units SW0′˜SW63′ can be designed with a combination of four switches, wherein the four switches are respectively used for connecting the driving circuit 2023, two input terminals I+ and I− of the sensing circuit 2021′ and the reference voltage terminal Vref. Comparatively, each of the switching signals G0S[0:3]˜G63S[0:3], produced by the control circuit 2022′, is designed as a 4 bits signal. For example, when signal value equals to [0001], it means selectively connecting to the driving circuit 2023; when signal value equals to [0010], it means selectively connecting to the input terminal I+ of the sensing circuit 2021′; when signal value equals to [0100], it means selectively connecting to the input terminal I− of the sensing circuit 2021′; and when signal value equals to [1000], it means selectively connecting to the reference voltage terminal Vref.

Accordingly, in practice, when the control circuit 2022′ controls any of the switching units SW11′˜SW50′, which is correspondingly connected with the driving lines D0˜D39 to selectively connect to the driving circuit 2023, the way of the control circuit 2022′ sequentially controlling all the switching units SW0′˜SW10′ and S61′˜S51′, which are correspondingly connected with the sensing lines S0˜S21, is to simultaneously control two switching units SW0′˜SW10′ and S61′˜S51′, which are connected with the sensing lines S0˜S21 each time to selectively connect to two input terminals I+ and I− of the sensing circuit 2021′ respectively for differential sensing.

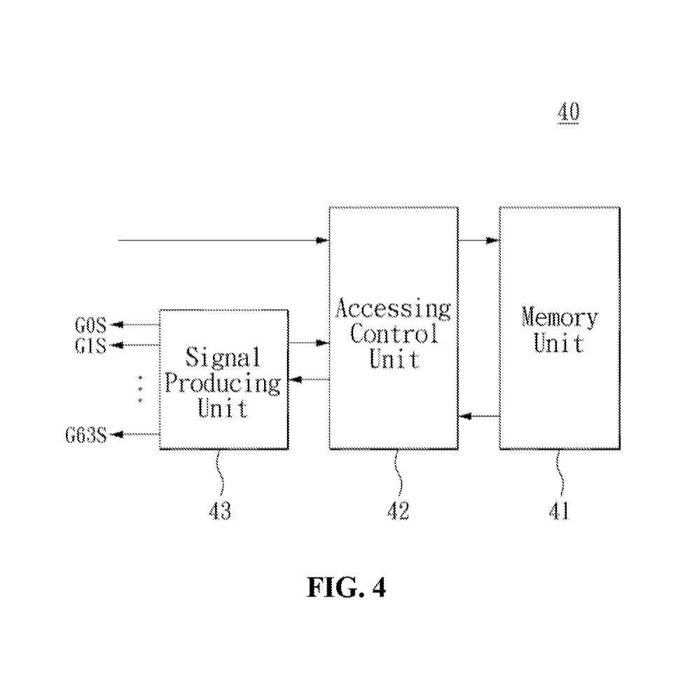

With reference to FIG. 4, FIG. 4 is a functional block diagram of a control circuit 40 in accordance with an embodiment of the present disclosure. The control circuit 40 can be used for accomplishing control circuits 2022 and 2022′ of the embodiments of FIG. 3A and FIG. 3B. The control circuit 40 comprises a memory unit 41, an accessing control unit 42, and a signal producing unit 43. The accessing control unit 42 is connected to the memory unit 41 for receiving corresponding relationship between the general pins and the sensing lines and driving lines that is defined by designers of the touch sensing device and for recording the corresponding relationship into the memory unit 41. The signal producing unit 43, connected to the accessing control unit 42, is used for obtaining the recorded corresponding relationship in the memory unit 41 through the accessing control unit 42 and for producing a plurality of switching signals. G0S˜G63S based on the corresponding relationship, so as to control operations of all of the switching units SW0˜SW63 and SW0′˜SW63 of FIG. 3A and FIG. 3B and further manage functions of all of the general pins G0˜G63.

It is to be noted that the switching signals G0S˜G63S would be different based on actual design of the switching unit. For example, if the switching units are designed as the switching units SW0˜S63 of FIG. 3A, the switching signals G0S˜G63S are then designed as the switching signals G0S[0:2]˜G63S[0:2] of FIG. 3A, and if the switching units are designed as the switching units SW0′˜S63′ of FIG. 3B, the switching signals G0S˜G63S are then designed as the switching signals G0S[0:3]˜G63S[0:3] of FIG. 3B.

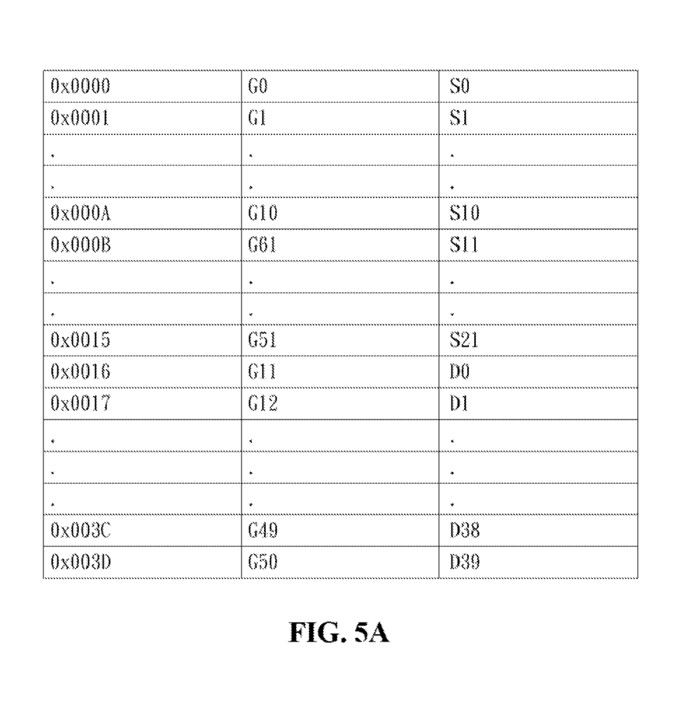

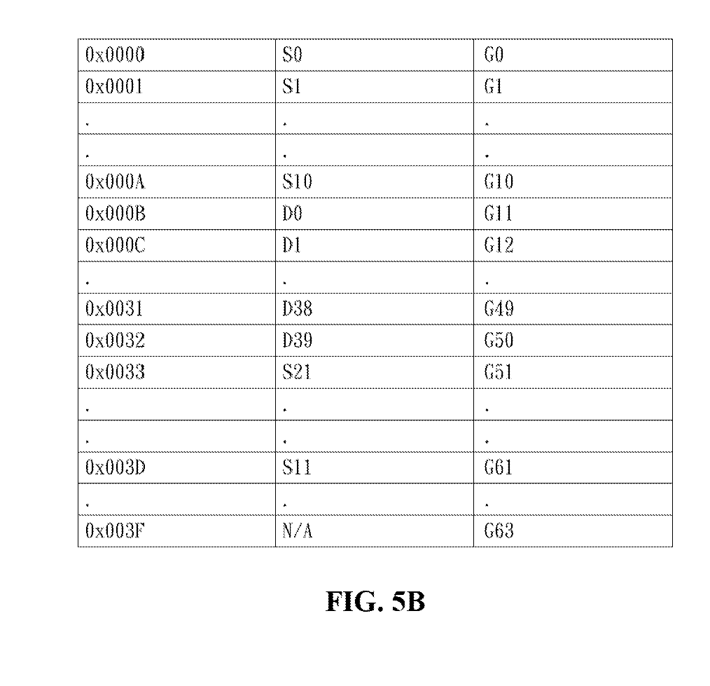

Continually, with reference to FIG. 2, FIG. 4 and FIG. 5A simultaneously, FIG. 5A is a diagram of corresponding relationship recorded by a memory unit in accordance with an embodiment of the present disclosure. The diagram of FIG. 5A illustrates to correspondingly record the corresponding relationship of the general pins G0˜G61 of the programmable controller 202 by using a benchmark of the driving lines D0˜D39 and the sensing lines S0˜S21 of the touch panel 201. In the design, the memory unit 41 would be noticed how many driving lines D0˜D39 and the sensing lines S0˜S21 the touch panel 201 has, it means that the memory unit 41 can be inputted with number information of the driving lines and the sensing lines. Moreover, the general pins G0˜G10 and G61˜G51, which are connected with the sensing lines S0˜S21, are sequentially recorded in registers of the memory unit 41 at addresses 0x0000˜0x0015, and the general pins G11˜G50, which are connected with the driving lines D0˜D39, are sequentially recorded in registers of the memory unit 41 at addresses 0x0016˜0x003D. For example, as shown in FIG. 5A, the general pin connected by the sensing line S21 is G51, so that value of the general pin G51 would be recorded in the register at address 0x0015; and the general pin connected by the driving line D38 is G49, so that value of the general pin G49 would be recorded in the register at address 0x003C.

With reference to FIG. 2, FIG. 4 and FIG. 5B simultaneously, FIG. 5B is a diagram of corresponding relationship recorded by a memory unit in accordance with another embodiment of the present disclosure. Different to the embodiment of FIG. 5A, the diagram of FIG. 5B illustrates to correspondingly record the corresponding relationship of the driving lines D0˜D39 and the sensing lines S0˜S21 of the touch panel 201 by using a benchmark of the general pins G0˜G63 of the programmable controller 202. The memory unit 41 would be inputted with number information of the general pins of the programmable controller 202. Moreover, registers of the memory unit 41 at addresses 0x0000˜0x003F are used for sequentially recording connecting status of the general pins G0˜G63 such as connecting sensing lines S0˜S21, connecting driving lines D0˜D39 or non-connecting. For example, as shown in FIG. 5B, the general pin G51 is correspondingly connected with the sensing line S21, so that value of the sensing line S21 is recorded in the register at address 0x0033; and the general pin G49 is correspondingly connected with the driving line D38, so that value of the driving line D38 is recorded in the register at address 0x0031.

It is to be noted that the recording methods of the corresponding relationship that are disclosed in the foregoing FIG. 5A and FIG. 5B are not for limiting the present disclosure, and volume of the memory unit 41 is based on the number of the sensing lines, number of driving lines, number of the general pins, and the like values.

In addition, it is to be noted that the programmable controller of the foregoing embodiment is designed with a single-chip system to directly integrate the driving circuit, the sensing circuit, the control circuit and the switching units. However, in other embodiments, the driving circuit and the sensing circuit would not be integrated with the switching units and the control circuit into a same chip. In other words, in other embodiments, the programmable controller can only comprise a plurality of switching units and a control circuit, and the driving circuit and the sensing circuit are independent of the programmable controller.

In conclusion, those embodiments of the present disclosure can increase application flexibility of the programmable controller, and improve utilization of all of the general pins of the programmable controller. Designers of the touch sensing device can set function of each general pin of the programmable controller according to outlet location of the sensing lines and the driving lines of the practical touch panel and location of the general pins of the programmable controller, thereby recording the corresponding relationship between the general pins and the sensing lines and driving lines into the programmable controller. Therefore, the programmable controller can control sequences of the driving circuit transmitting driving signals to the driving lines and the sensing circuit receiving the sensing signals from the sensing lines. Besides, an interchangeable defined general pin function provided by the programmable controller can further eliminate obsession of circuit layout on the circuit board or flexible board, and to make circuit layout of the wires which are used for connecting the touch panel and the programmable controller on the circuit board or the flexible board conforming to wiring rule without cross-alignment occurring.

The foregoing description is the embodiment of the present disclosure only, and not intent to limit the scope of the present disclosure.

What is claimed is:

1. A programmable controller, comprising:
a plurality of general pins;
a control circuit for recording corresponding relationship between the general pins and a plurality of sensing lines and a plurality of driving lines of a touch panel; and
a plurality of switching units correspondingly connected to the general pins and separately receiving a switching signal produced by the control circuit, wherein the control circuit produces the switching signal based on the corresponding relationship, and wherein each of the switching units selectively connects the correspondingly connected general pin to a sensing circuit or a driving circuit based on the received switching signal.

2. The programmable controller of claim 1, wherein the control circuit further controls switching operation of the switching units through controlling producing sequence of the switching signal.

3. The programmable controller of claim 2, wherein when the control circuit controls each of the general pins, which is correspondingly connected with the during lines, to selectively connect to the driving circuit for transmitting a driving signal produced by the driving circuit to the correspondingly connected driving line, the control circuit further controls all of the general pins, which are correspondingly connected with the sensing lines, to selectively connect to the sensing circuit in sequence for transmitting a sensing signal coupling-produced by the correspondingly connected sensing line to the sensing circuit.

4. The programmable controller of claim 3, wherein the control circuit further simultaneously controls two switching units, which are correspondingly connected to the sensing lines, to selectively connect to two input terminals of the sensing circuit.

5. The programmable controller of claim 1, wherein each of the switching units further selectively connects the correspondingly connected general pin to a reference voltage terminal or a high impedance terminal based on the received switching signal.

6. The programmable controller of claim 1, wherein each of the switching units is designed with a combination of switches, a selector, or a multiplexer.

7. The programmable controller of claim 1, wherein the control circuit comprises:
a memory unit;
an accessing control unit connected with the memory unit for receiving the corresponding relationship and recording the corresponding relationship into the memory unit; and
a signal producing unit connected to the accessing control unit for obtaining the corresponding relationship recorded in the memory unit through the accessing control unit and producing the switching signals based on the corresponding relationship.

8. A touch sensing device, comprising:
a touch panel comprising a plurality of sensing lines and a plurality of driving lines;
a programmable controller comprising:
a plurality of general pins;
a control circuit for recording corresponding relationship between the general pins and
a plurality of sensing lines and a plurality of driving lines of a touch panel; and
a plurality of switching units correspondingly connected to the general pins and separately receiving a switching signal produced by the control circuit, wherein the control circuit produces the switching signal based on the corresponding relationship, and wherein each of the switching units selectively connects the correspondingly connected general pin to a sensing circuit or a driving circuit based on the received switching signal.

9. The touch sensing device of claim 8, wherein the control circuit further controls switching operation of the switching units through controlling producing sequence of the switching signal.

10. The touch sensing device of claim 9, wherein when the control circuit controls each of the general pins, which is correspondingly connected with the driving lines, to selectively connect to the driving circuit for transmitting a driving signal produced by the driving circuit to the correspondingly connected driving line, the control circuit further controls all of the general pins, which are correspondingly connected with the sensing lines, to selectively connect to the sensing circuit in sequence for transmitting a sensing signal coupling-produced by the correspondingly connected sensing line to the sensing circuit.

11. The touch sensing device of claim 10, wherein the control circuit further simultaneously controls two switching units, which are correspondingly connected to the sensing lines, to selectively connect to two input terminals of the sensing circuit.

12. The touch sensing device of claim 8, wherein each of the switching units further selectively connects the correspondingly connected general pin to a reference voltage terminal or a high impedance terminal based on the received switching signal.

13. The touch sensing device of claim 8, wherein each of the switching units is designed with a combination of switches, a selector or a multiplexer.

14. The touch sensing device of claim 8, wherein the programmable controller is a single-chip system for integrating the control circuit, the switching units, the driving circuit, and the sensing circuit.

15. The touch sensing device of claim 8, wherein the control circuit comprises:
a memory unit;
an accessing control unit connected with the memory unit for receiving the corresponding relationship and recording the corresponding relationship into the memory unit; and
a signal producing unit connected to the accessing control unit for obtaining the corresponding relationship recorded in the memory unit through the accessing control unit and producing the switching signals based on the corresponding relationship.
